(19) United States
(12) Patent Application Publication
(10) Pub. No.: US 2025/0210434 A1
(43) Pub. Date: Jun. 26, 2025

(54) SEMICONDUCTOR PACKAGE

(71) Applicant: SAMSUNG ELECTRONICS CO., LTD., SUWON-SI (KR)

(72) Inventors: Sang Ho SHIN, Suwon-si (KR); Young Lyong KIM, Suwon-si (KR)

(21) Appl. No.: 18/794,045

(22) Filed: Aug. 5, 2024

(30) Foreign Application Priority Data
Dec. 20, 2023 (KR) 10-2023-0187250

(51) Int. Cl. H01L 23/31; H01L 23/00; H01L 23/498; H01L 23/538; H01L 25/18; H10B 80/00

(52) U.S. Cl. CPC H01L 23/3135; H01L 23/315; H01L 23/5383; H01L 25/18; H01L 23/49816; H01L 23/5385; H01L 23/562; H01L 24/16; H01L 24/17; H01L 24/32; H01L 24/33; H01L 24/73; H01L 2224/16227; H01L 2224/17181; H01L 2224/32225; H01L 2224/33181; H01L 2224/73204; H10B 80/00

(57) ABSTRACT

A semiconductor package includes: a substrate; first semiconductor chips mounted on the substrate; a second semiconductor chip mounted on the substrate; a first molding member covering sides of the first semiconductor chips; and a second molding member covering the first semiconductor chips and the second semiconductor chip. Each of the first semiconductor chip includes a plurality of semiconductor chips that are stacked on each other along a first direction. The first molding member includes recesses extending along the first direction. The recesses include first portions, which extend to edges of the first molding member and have a first width, and second portions, which are connected to the first portions and are positioned more inward into the first molding member than the first portions. The second portions have a second width that is greater than the first width, and the second molding member fills at least parts of the recesses.

### CROSS-REFERENCE TO RELATED APPLICATION

This application claims priority under 35 USC § 119 to Korean Patent Application No. 10-2023-0187250 filed on Dec. 20, 2023 in the Korean Intellectual Property Office, the disclosure of which is incorporated by reference herein in its entirety.

### TECHNICAL FIELD

Embodiments of the present inventive concept relates to a semiconductor package.

### DISCUSSION OF THE RELATED ART

For a semiconductor package with high-performance semiconductor chips embedded therein, wafer level molding can be performed after mounting heterogeneous chips onto a substrate of the semiconductor package.

In the case of a semiconductor package that includes an interposer, issues such as warpage due to mismatch in the coefficient of thermal expansion (CTE) between the interposer and the molding material of chips, deterioration in the filling properties of an underfill resin, and cracking between a die and the molding material may occur during a molding process.

### SUMMARY

According to embodiments of the present inventive concept, a semiconductor package includes: a substrate; first semiconductor chips mounted on the substrate; a second semiconductor chip mounted on the substrate and spaced apart from the first semiconductor chips; a first molding member covering sides of each of the first semiconductor chips; and a second molding member covering the first semiconductor chips and the second semiconductor chip, and disposed on the substrate. Each of the first semiconductor chip includes a plurality of semiconductor chips that are stacked on each other along a first direction. The first molding member includes recesses, which are formed to extend along the first direction. The recesses include first portions, which extend to edges of the first molding member and have a first width, and second portions, which are connected to the first portions and are positioned more inward into the first molding member than the first portions. The second portions have a second width that is greater than the first width, and the second molding member fills at least parts of the recesses.

According to embodiments of the present inventive concept, a semiconductor package includes: an interposer structure; first semiconductor chips mounted on the interposer structure and including a stack of a plurality of semiconductor chips; a plurality of first bumps electrically connecting the interposer structure to the first semiconductor chips and disposed between the interposer structure and the first semiconductor chips; a first molding member at least partially surrounding the first semiconductor chips and including a plurality of recesses, which are formed in a stacking direction of the plurality of semiconductor chips; and a second molding member covering the first semiconductor chips and disposed on the interposer structure, wherein the recesses have first areas and second areas, which are formed on the first areas, and include first recesses and second recesses, wherein the first recesses are formed in the first areas and include first portions, which have a first width, and second portions, which have a second width that is greater than the first width, wherein the second recesses are formed in the second areas and include third portions, which have a third width, and fourth portions, which have a fourth width that is greater than the third width, and the second molding member fills the first recesses and the second recesses.

According to embodiments of the present inventive concept, a semiconductor package includes: a circuit board; an interposer structure disposed on the circuit board; first solder balls electrically connecting the interposer structure to the circuit board; memory chips mounted on the interposer structure and including a stack of a plurality of semiconductor chips; a logic chip spaced apart from the memory chips and mounted on the interposer structure; a plurality of first bumps electrically connecting the interposer structure to the memory chips, and electrically connecting the interposer structure to the logic chip, wherein the plurality of first bumps are disposed between the interposer structure and the memory chips and between the interposer structure and the logic chip; a first molding member at least partially surrounding the memory chips and including a plurality of recesses, which extend in a first direction; and a second molding member covering the memory chips and the logic chip, and covering the first molding member, wherein the recesses include first recesses, which are formed in first areas, and second recesses, which are formed in second areas that are formed on the first areas. The first recesses include first portions, which have a first width, and second portions, which have a second width that is greater than the first width. The second recesses include third portions, which have a third width, and fourth portions, which have a fourth width that is greater than the third width. The third width is greater than the first width. The fourth width is greater than the second width. The second molding member fills the first recesses and the second recesses and has a T shape, and in the recesses, sides of the first molding member have a stair-like shape.

### BRIEF DESCRIPTION OF THE DRAWINGS

The above and features of the present inventive concept will become more apparent by describing in detail example embodiments thereof with reference to the attached drawings, in which:

FIG. 1 is a plan view illustrating a semiconductor package according to embodiments of the present inventive concept.

FIG. 2 is a cross-sectional view taken along line A-A of FIG. 1.

FIG. 3 is an enlarged perspective view of part P of FIG. 1.

FIG. 4 is an enlarged perspective view of part Q of FIG. 3.

FIG. 5 is a cross-sectional view taken along line B-B of FIG. 4.

FIGS. 6 and 7 are cross-sectional views taken along line C-C of FIG. 4.

FIGS. 8 and 9 are cross-sectional views taken along line D-D of FIG. 4.

FIGS. 10, 11, 12 and 13 illustrate how to form recesses in a semiconductor package according to embodiments of the present inventive concept.

FIGS. 14 and 15 illustrate a semiconductor package according to embodiments of the present inventive concept.

FIG. 16 is an enlarged drawing of part K of FIG. 15.

FIG. 17 is a cross-sectional view taken along line E-E of FIG. 16.

FIGS. 18 and 19 are cross-sectional views taken along line F-F of FIG. 16.

FIGS. 20 and 21 are cross-sectional views taken along line G-G of FIG. 16.

FIGS. 22, 23 and 24 illustrate recesses in a semiconductor package according to embodiments of the present inventive concept.

FIGS. 25, 26 and 27 are diagrams illustrating recesses in a semiconductor package according to embodiments of the present inventive concept.

FIGS. 28, 29 and 30 are diagrams illustrating recesses in semiconductor packages according to embodiments of the present inventive concept.

### DETAILED DESCRIPTION OF THE EMBODIMENTS

In this specification, although terms such as “first,” “second,” etc. are used to describe various elements or components, but these elements or components are not limited by these terms. These terms are merely used to distinguish one element or component from another. Therefore, a first element or component mentioned below may be a second element or component without departing from the spirit and scope of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, in the example, terms “below” and “beneath” may encompass both an orientation of above, below and beneath. The device may be otherwise oriented (e.g., rotated 90 degrees or at other orientations) and the spatially relative descriptors used herein may be interpreted accordingly.

Embodiments of the present disclosure will hereinafter be described in detail with reference to the attached drawings. The same reference numerals are used for the same elements in the drawings and specification, and thus, redundant descriptions thereof will be omitted or briefly discussed.

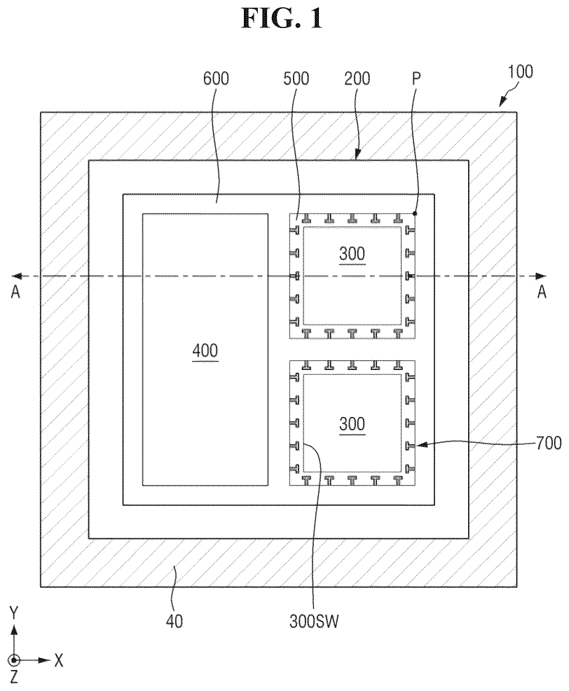

A semiconductor package according to some embodiments of the present inventive concept will hereinafter be described with reference to FIGS. 1 through 9.

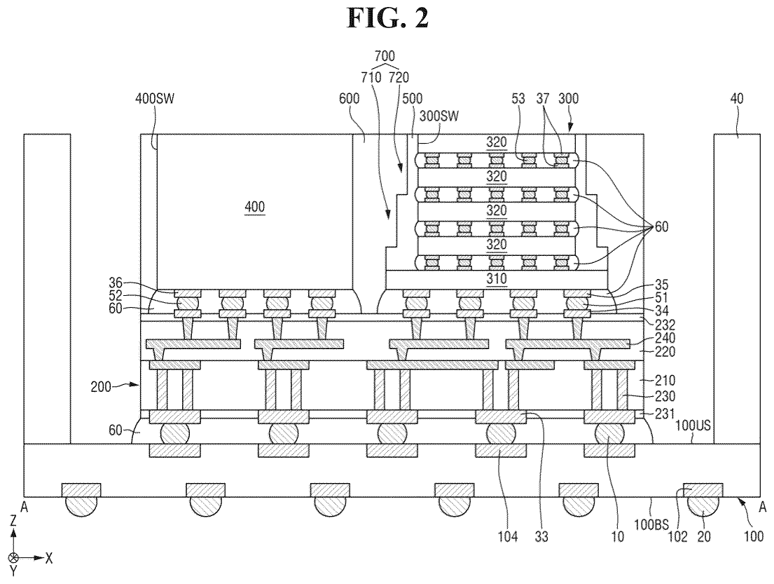

FIG. 1 is a plan view illustrating a semiconductor package according to embodiments of the present inventive concept. FIG. 2 is a cross-sectional view taken along line A-A of FIG. 1.

Referring to FIGS. 1 and 2, the semiconductor package according to embodiments of the present inventive concept may include a circuit board 100, an interposer structure 200, first semiconductor chips 300, a second semiconductor chip 400, a first molding member 500, a second molding member 600, and a stiffener 40.

The circuit board 100 may extend in a first direction X. In this specification, the first direction X, a second direction Y, and a third direction Z may intersect one another. The first, second, and third directions X, Y, and Z may be substantially perpendicular to one another.

The circuit board 100 may be a package substrate. The circuit board 100 may be a printed circuit board (PCB). The circuit board 100 may have upper and lower surfaces 100US and 100BS that are opposite to each other. The upper surface 100US of the circuit board 100 may face the interposer structure 200 that will be described later.

The circuit board 100 may include first board pads 102 and second board pads 104. The first board pads 102 and the second board pads 104 may be used to electrically connect the circuit board 100 to other components. In embodiments of the present inventive concept, the first board pads 102 may be formed near the lower surface 100BS of the circuit board 100, and the second board pads 104 may be formed near the upper surface 100US of the circuit board 100.

The first board pads 102 may be exposed from the lower surface 100BS of the circuit board 100, and the second board pads 104 may be exposed from the upper surface 100US of the circuit board 100. FIG. 2 illustrates that there are provided six first board pads 102 and five second substrate pads 104, but the present inventive concept is not limited thereto.

The circuit board 100 may be mounted on the mainboard of an electronic device. For example, second solder balls 20, which are connected to the first board pads 102, may be provided. The circuit board 100 may be mounted on the mainboard of an electronic device through the second solder balls 20. The circuit board 100 may be a ball grid array (BGA) board, but the present inventive concept is not limited thereto.

The second solder balls 20 may be, for example, solder bumps, but the present inventive concept is not limited thereto. The second solder balls 20 may have various shapes such as a land shape, a ball shape, a pin shape, a pillar shape, etc. The number, spacing, and arrangement pattern of the second solder balls 20 are not particularly limited and may vary depending on the design.

The interposer structure 200 may extend in the first direction X and may be arranged on the upper surface 100US of the circuit board 100. The interposer structure 200 may have upper and lower surfaces that are opposite to each other. The upper surface of the interposer structure 200 may face the first semiconductor chips 300 and the second semiconductor chip 400 that will be described later. The lower surface of the interposer structure 200 may face the circuit board 100.

The interposer structure 200 can facilitate connections between the circuit board 100 and the first semiconductor chips 300 and between the circuit board 100 and the second semiconductor chip 400, and may prevent warpage of the semiconductor package according to embodiments of the present inventive concept. For example, the first semiconductor chips 300 and the second semiconductor chip 400 may be stacked on the circuit board 100 through the interposer structure 200. The first semiconductor chips 300 and the second semiconductor chip 400 may be electrically connected to the circuit board 100 through the interposer structure 200.

The interposer structure 200 may be mounted on the upper surface 100US of the circuit board 100. For example, first solder balls 10 may be formed between the circuit board 100 and the interposer structure 200. The second board pads 104 and first interposer pads 33 that will be described later may be connected by the first solder balls 10. For example, the first solder balls 10 may be disposed between the second board pads 104 and the first interposer pads 33. Thus, the circuit board 100 and the interposer structure 200 may be electrically connected to each other.

The first solder balls 10 may be solder bumps including a low-melting-point metal, such as tin (Sn) or a Sn alloy, but the present inventive concept is not limited thereto. The first solder balls 10 may have various shapes such as a land shape, a ball shape, a pin shape, a pillar shape, etc. The first solder balls 10 may be formed as single layers or multilayers. When formed as single layers, the first solder balls 10 may include, for example, tin-silver (Sn—Ag) solder or copper (Cu). When formed as multilayers, the first solder balls 10 may include, for example, a Cu filler and solder. The number, spacing, and arrangement pattern of the first solder balls 10 are not particularly limited and may vary depending on the design.

In embodiments of the present inventive concept, the interposer structure 200 may include an interposer 210, an interlayer insulating layer 220, a first passivation film 231, a second passivation film 232, redistribution layers 240, through vias 230, the first interposer pads 33, and the second interposer pads 34.

The interposer 210 may be disposed on the circuit board 100. For example, the interposer 210 may be a silicon (Si) substrate. The interposer 210 may be, for example, a Si interposer, but the present inventive concept is not limited thereto. In embodiments of the present inventive concept, the interposer 210 may be formed as one of a Si substrate, an organic substrate, a plastic substrate, or a glass substrate.

The interlayer insulating layer 220 may be formed on the interposer 210. The interlayer insulating layer 220 may include an insulating material. For example, the interlayer insulating layer 220 may include at least one of silicon oxide, silicon nitride, silicon oxynitride, and/or a low-k material with a smaller lower dielectric constant than that of silicon oxide, but the present inventive concept is not limited thereto.

The first interposer pads 33 and the second interposer pads 34 may both be used to electrically connect the interposer structure 200 to other components. For example, the first interposer pads 33 may be exposed from the lower surface of the interposer structure 200, and the second interposer pads 34 may be exposed from the upper surface of the interposer structure 200.

The first interposer pads 33 and the second interposer pads 34 may each include a metallic material such as aluminum (Al), Cu, nickel (Ni), tungsten (W), platinum (Pt), gold (Au), etc., but the present inventive concept is not limited thereto.

The first interposer pads 33 and the second interposer pads 34 are illustrated as being rectangular in shape, but the present inventive concept is not limited thereto. In addition, the first interposer pads 33 and the second interposer pads 34 may have various other shapes such as a circular, oval, or polygonal.

Within the interposer structure 200, wiring patterns for electrically connecting the first interposer pads 33 and the second interposer pads 34 to each other may be formed. For example, the through vias 230 and the redistribution layers 240 may be formed within the interposer structure 200.

The through vias 230 may extend from the lower surface to the upper surface of the interposer 210, and may penetrate the interposer 210. The through vias 230 may be through silicon vias (TSVs).

The through vias 230 may be electrically connected to the first interposer pads 33. The through vias 230 may also be electrically connected to the circuit board 100 through the first interposer pads 33, the first solder balls 10, and the second board pads 104.

Each of the through vias 230 may have a pillar shape and may include a barrier film on their outer surface and an embedded conductive layer within the barrier film. For example, the barrier film may include at least one of Ti, TiN, Ta, TaN, Ru, Co, Mn, WN, Ni, and/or NiB. For example, the embedded conductive layer may include at least one of Cu, a Cu alloy (e.g., CuSn, CuMg, CuNi, CuZn, CuPd, CuAu, CuRe, or CuW), W, a W alloy, Ni, Ru, and/or Co.

The redistribution layers 240 may be disposed within the interlayer insulating layer 220. The redistribution layers 240 may be electrically connected to the second interposer pads 34. Through the redistribution layers 240, the interposer structure 200 may be electrically connected to the first semiconductor chips 300 and the second semiconductor chip 400. The redistribution layers 240 may include a metallic material such as Cu or Al, but the present inventive concept is not limited thereto.

The first passivation film 231 may be disposed on the interposer 210. For example, the first passivation film 231 may extend along the bottom surface of the interposer 210. The first interposer pads 33 may be connected to the through vias 230 by penetrating the first passivation film 231. The first interposer pads 33 may be exposed by the first passivation film 231.

The second passivation film 232 may be disposed on the interlayer insulating layer 220. For example, the second passivation film 232 may extend along the upper surface of the interlayer insulating layer 220. The second interposer pads 34 may be connected to the redistribution layers 240 by penetrating the second passivation film 232. The second interposer pads 34 may be exposed by the second passivation film 232.

In embodiments of the present inventive concept, the height, in the third direction Z, of the second passivation film 232 may be less than the height, in the third direction Z, of the second interposer pads 34. For example, the second interposer pads 34 may protrude in the third direction Z beyond the second passivation film 232. The first interposer pads 33 may protrude in the third direction Z beyond the first passivation film 231.

For example, each of the first and second passivation films 231 and 232 may include silicon nitride. In addition, the first and second passivation films 231 and 232 may be formed of, for example, a passivation material, benzocyclobutene (BCB), polybenzoxazole, polyimide, epoxy, silicon oxide, silicon nitride, or a combination thereof.

The first semiconductor chips 300 may be mounted on the interposer structure 200. The first semiconductor chips 300 may include first chip pads 35. The first chip pads 35 may be used to electrically connect the first semiconductor chips 300 to other components. For example, the first chip pads 35 may be exposed from the lower surfaces of the first semiconductor chips 300. For example, the first chip pads 35 may be disposed on the lower surfaces of the first semiconductor chips 300.

The first chip pads 35 may include a metallic material such as Al, Cu, Ni, W, Pt, or Au, but the present inventive concept is not limited thereto.

The first semiconductor chips 300 may be electrically connected to the interposer structure 200. For example, a plurality of first bumps 51 may be formed between the interposer structure 200 and the first semiconductor chips 300. The first chip pads 35 and the second interposer pads 34 may be connected to each other through the first bumps 51.

The first bumps 51 may be solder bumps including a low-melting-point metal, such as Sn or a Sn alloy, but the present inventive concept is not limited thereto. The first bumps 51 may have various other shapes such as a land shape, a ball shape, a pin shape, a pillar shape, etc. The first bumps 51 may include under bump metallurgies (UBMs).

The first bumps 51 may be formed as single layers or multilayers. When formed as single layers, the first bumps 51 may include, for example, Sn—Ag solder or Cu, but the present inventive concept is not limited thereto. When formed as multilayers, the first bumps 51 may include, for example, a Cu filler and solder, but the present inventive concept is not limited thereto. The number, spacing, and arrangement pattern of the first bumps 51 are not particularly limited and may vary depending on the design.

The first semiconductor chips 300 may be memory chips. For example, the first semiconductor chips 300 may be volatile memories such as dynamic random-access memories (DRAMs) or static random-access memories (SRAMs), or nonvolatile memories such as flash memories, phase-change random-access memories (PRAMs), magnetoresistive random-access memories (MRAMs), ferroelectric random-access memories (FeRAMs), or resistive random-access memories (RRAMs).

In embodiments of the present inventive concept, the first semiconductor chips 300 may be stacked memories such as high bandwidth memories (HBMs). Each of the first semiconductor chips 300 may include a buffer die 310, which serves as a circuit, and a plurality of memory dies (or chips) 320, which are sequentially stacked on the buffer die 310. For example, each of the first semiconductor chips 300 may include a plurality of semiconductor chips that are stacked along a stacking direction.

The buffer die 310 and the memory dies 320 may be physically and/or electrically connected to each other through third chip pads 37 and third bumps 53. For example, the third chip pads 37 may be disposed on upper surfaces and lower surfaces of the memory dies 320 and an upper surface of the buffer die 310, and the third bumps 53 may be disposed between the third chip pads 37, which are disposed on the lower surfaces of the memory dies 320, and the third chip pads 37, which are disposed on the upper surfaces of the memory dies 320. For example, third bumps 320 may be disposed between third chip pads 37, which are disposed on a lower surface of a first memory die 320, and third chip pads 37, which are disposed on an upper surface of a second memory die 320 that is adjacent to and below the first memory die 320. In another example, the third bumps 53 may be disposed between third chip pads 37, which are disposed on a lower surface of a lowermost memory die 320 of the stack of memory dies 320, and the third chip pads 37, which are disposed on the upper surface of the buffer die 310. In embodiments of the present inventive concept, the buffer die 310 and the memory dies 320 may be electrically connected to one another through TSVs. The description of the third chip pads 37 may be substantially the same as that of the first chip pads 35. Similarly, the description of the third bumps 53 may be substantially the same as that of the first bumps 51.

The second semiconductor chip 400 may be spaced apart from the first semiconductor chips 300 and mounted on the interposer structure 200. The second semiconductor chip 400 may include second chip pads 36. The second chip pads 36 may be used to electrically connect the second semiconductor chip 400 to other components. For example, the second chip pads 36 may be exposed from the lower surface of the second semiconductor chip 400. The description of the second chip pads 36 may be substantially the same as that of the first chip pads 35.

The second semiconductor chip 400 may be electrically connected to the interposer structure 200. For example, a plurality of second bumps 52 may be formed between the interposer structure 200 and the second semiconductor chip 400. The second chip pads 36 may be connected to the second interposer pads 34 through the second bumps 52. The description of the second bumps 52 may be substantially the same as that of the first bumps 51.

The second semiconductor chip 400 may be a logic chip. For example, the second semiconductor chip 400 may be an application processor (AP) such as a central processing unit (CPU), a graphics processing unit (GPU), a field-programmable gate array (FPGA), a digital signal processor, an encryption processor, a microprocessor, a microcontroller, or an application-specific integrated circuit (ASIC), but the present inventive concept is not limited thereto.

The first semiconductor chip 300 may be an HBM, and the second semiconductor chip 400, which is spaced apart from the first semiconductor chip 300, may be an ASIC chip.

An underfill 60 may fill the space between the circuit board 100 and the interposer structure 200. The underfill 60 may cover the first solder balls 10. The underfill 60 may fill the gap between the circuit board 100 and the interposer structure 200.

The underfill 60 may also fill the gaps between the interposer structure 200 and the first semiconductor chips 300 and between the interposer structure 200 and the second semiconductor chip 400. The underfill 60 may cover the first bumps 51 and the second bumps 52. The underfill 60 may fill the gaps between the interposer structure 200 and the first semiconductor chips 300 and between the interposer structure 200 and the second semiconductor chip 400.

The underfill 60 may include, for example, an epoxy-based resin, BCB, or polyimide, but the present inventive concept is not limited thereto. The underfill 60 may include an insulating polymer material such as an epoxy molding compound (EMC), but the present inventive concept is not limited thereto.

The first molding member 500 may surround sides 300SW of the first semiconductor chips 300 and the sides of the underfill 60 that exists between the memory dies 320. The first molding member 500 may contact the sides of the memory dies 320 and the sides of the underfill 60 that are between the memory dies 320. The sides 300SW of the first semiconductor chip 300 may be the sides of the memory dies 320.

The first molding member 500 might not cover the upper surface of the uppermost memory die 320. The upper surface of the uppermost memory die 320 may be exposed to the outside from the first molding member 500.

The first molding member 500 may cover the upper surface of the buffer die 310. The first molding member 500 might not cover the sides of the buffer die 310. For example, a side of the first molding member 500 may be substantially coplanar with a side of the buffer die 310.

The first molding member 500 may include an insulating polymer material such as an EMC, but the present inventive concept is not limited thereto. For example, the first molding member 500 may include an epoxy-based resin, BCB, or polyimide. In addition, the first molding member 500 may include, for example, a silica filler or flux.

The second molding member 600 may at least partially surround the first semiconductor chips 300 and the second semiconductor chip 400. The second molding member 600 may at least partially surround sides 400SW of the second semiconductor chip 400. The second molding member 600 may at least partially surround the underfill 60, which is formed on the interposer structure 200. The second molding member 600 may at least partially surround the first molding member 500. The second molding member 600 may fill at least parts of recesses 700. The second molding member 600 may at least partially surround the sides of the buffer die 310.

The second molding member 600 might not cover the upper surfaces of the first semiconductor chips 300, the upper surface of the second semiconductor chip 400, and the upper surface of the first molding member 500. The second molding member 600 may expose the upper surfaces of the first semiconductor chips 300, the upper surface of the second semiconductor chip 400, and the upper surface of the first molding member 500. For example, an upper surface of the second molding member 600, the upper surfaces of the first semiconductor chips 300, the upper surface of the second semiconductor chip 400, and the upper surface of the first molding member 500 may be substantially coplanar.

The second molding member 600 may include an insulating polymer material such as an EMC, but the present inventive concept is not limited thereto. For example, the second molding member 600 may include an epoxy-based resin, BCB, or polyimide. In another example, the second molding member 600 may include a silica filler or flux. In embodiments of the present inventive concept, the second molding member 600 may include the same material as that of the first molding member 500. In addition, in embodiments of the present inventive concept, the second molding member 600 may include a different material from the first molding member 500.

The stiffener 40 may be disposed on the upper surface 100US of the circuit board 100. The stiffener 40 may be spaced apart from the interposer structure 200. The stiffener 40 may at least partially surround the interposer structure 200. The stiffener 40 might not contact the underfill 60. The stiffener 40 may prevent warpage in the circuit board 100.

The stiffener 40 may be formed of a metal material, such as Al, Ag, Sn, Au, Ni, lead (Pb), Ti, or an alloy thereof. An adhesive layer may be disposed between the stiffener 40 and the circuit board 100. The adhesive layer may be, for example, a thermally conductive adhesive tape, a thermally conductive grease, or a thermally conductive adhesive.

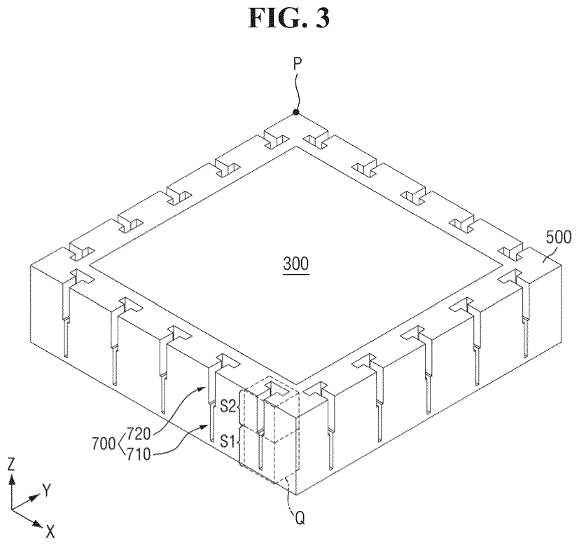

FIG. 3 is an enlarged perspective view of part P of FIG. 1.

Referring to FIG. 3, a first semiconductor chip 300 may be surrounded by the first molding member 500.

The sides of the first semiconductor chip 300 may be surrounded by the first molding member 500. The upper surface of the first semiconductor chip 300 might not be covered by the first molding member 500. The upper surface of the first semiconductor chip 300 may be exposed in the third direction Z from the first molding member 500.

The first molding member 500 may include a plurality of recesses 700. FIG. 3 illustrates that five recesses 700 are provided on each side of the first molding member 500, but the present inventive concept is not limited thereto.

The recesses 700 may be formed to extend along the stacking direction of a plurality of memory dies 320 that are included in the first semiconductor chip 300. For example, each of the recesses 700 may extend in a vertical direction. Each of the recesses 700 may include first and second areas S1 and S2. The second area S2 may be formed on the first area S1.

The recesses 700 may include first recesses 710, which are formed in first areas S1, and second recesses 720, which are formed in second areas S2. The second recesses 720 may be formed on the first recesses 710. The first recesses 710 may be formed before the second recesses 720, but the present inventive concept is not limited thereto. The length, in the third direction Z, of the first recesses 710 may be smaller than the length, in the third direction Z, of the second recesses 720, but the present inventive concept is not limited thereto. For example, the length, in the third direction Z, of the first recesses 710 may be the same as the length, in the third direction Z, of the second recesses 720.

FIG. 3 illustrates that the first recesses 710 do not extend to the bottom surface of the first molding member 500. For example, bottom surfaces of the first recesses 710 are spaced apart from the bottom surface of the first molding member 500. However, the present inventive concept is not limited thereto. For example, the first recesses 710 may extend to the bottom surface of the first molding member 500.

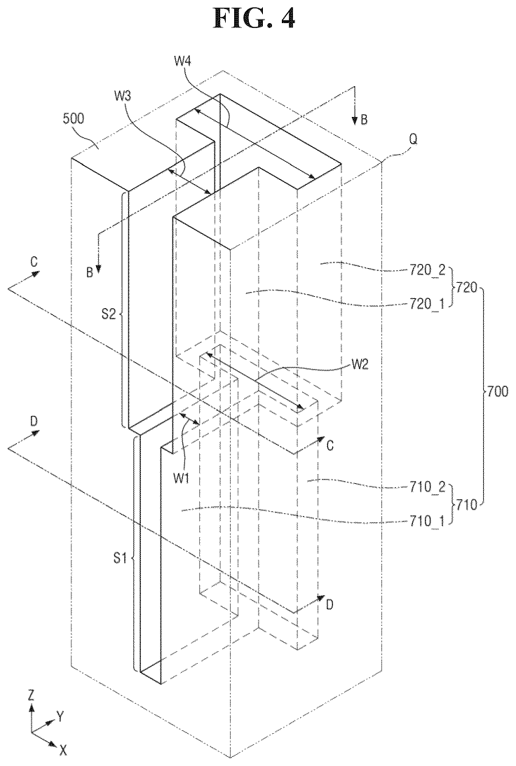

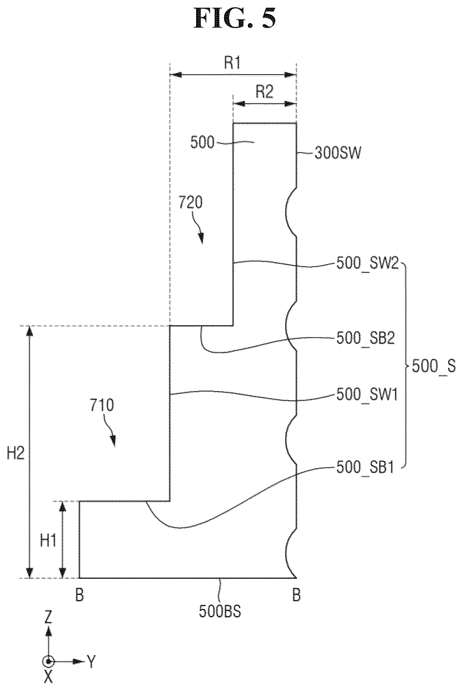

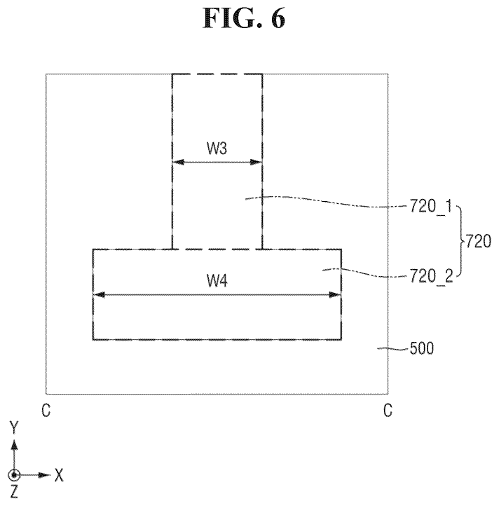

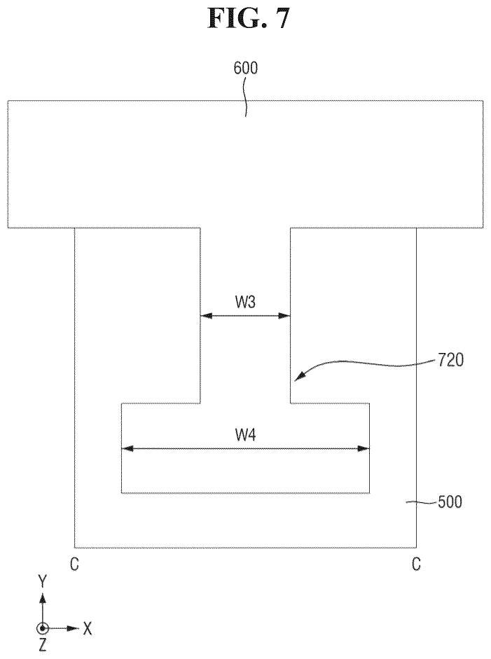

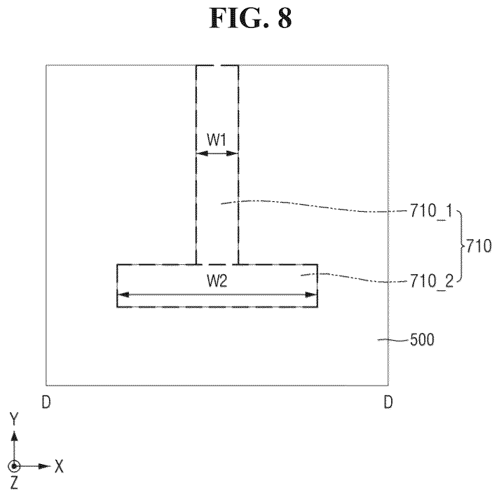

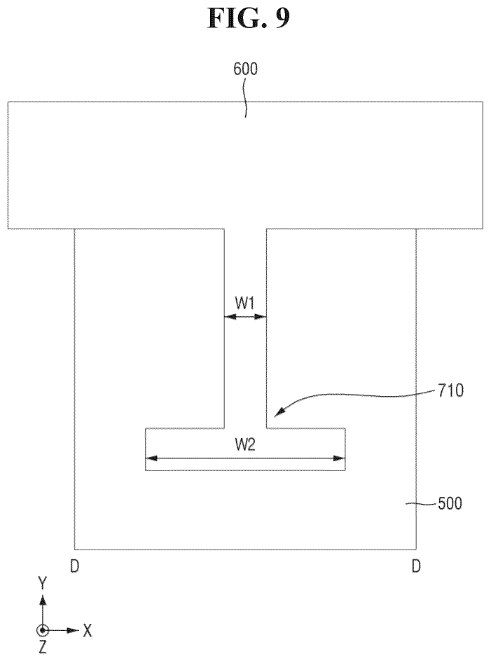

FIG. 4 is an enlarged perspective view of part Q of FIG. 3. FIG. 5 is a cross-sectional view taken along line B-B of FIG. 4. FIGS. 6 and 7 are cross-sectional views taken along line C-C of FIG. 4. FIGS. 8 and 9 are cross-sectional views taken along line D-D of FIG. 4.

Referring to FIG. 4, a first recess 710 of a recess 700, which is formed in a first area S1, may include a first portion 710_1 and a second portion 710_2, which is connected to the first portion 710_1. The first portion 710_1 may contact the edge of the first molding member 500. The second portion 710_2 may be disposed more inwardly than the first portion 710_1, in the first molding member 500.

A second recess 20 of the recess 700, which is formed in a second area S2, may include a third portion 720_1 and a fourth portion 720_2. The third portion 720_1 may contact the edge of the first molding member 500. The fourth portion 720_2 may be disposed more inwardly than the third portion 720_1, in the first molding member 500.

The first portion 710_1 of the first recess 710 may have a first width W1. For example, the first width W1 of the first portions 710_1 may be substantially constant along the stacking direction (e.g., the third direction Z). The second portion 710_2 of the first recess 710 may have a second width W2. For example, the second width W2 of the second portions 710_2 may be substantially constant along the stacking direction. The second width W2 may be greater than the first width W1.

In an embodiments of the present inventive concept, the first width W1 of the first portion 710_1 may narrow down in the stacking direction of the first semiconductor chip 300. For example, the first width W1 of the first portion 710_1 may decrease in a stepwise fashion as it goes down in the stacking direction.

In an embodiments of the present inventive concept, the second width W2 of the second portion 710_2 may also narrow down in the stacking direction of the first semiconductor chip 300. For example, the second width W2 of the second portion 710_2 may decrease in a stepwise fashion as it goes down in the stacking direction.

The third portion 720_1 of the second recess 720 may have a third width W3. The fourth portion 720_2 of the second recess 720 may have a fourth width W4. The fourth width W4 may be greater than the third width W3.

The third width W3 of the second recess 720 may be greater than the first width W1 of the first recess 710. The fourth width W4 of the second recess 720 may be greater than the second width W2 of the first recess 710.

The third and fourth widths W3 and W4 may also narrow down in the stacking direction of the first semiconductor chip 300. For example, the third and fourth widths W3 and W4 may decrease in a stepwise fashion as they go down in the stacking direction.

In an embodiment of the present inventive concept, the third width W3 may be the same as the first width W1, and the fourth width W4 may be the same as the second width W2.

The third portion 720_1 of the second recess 720 may be formed on the first part 710_1 of the first recess 710. The fourth portion 720_2 of the second recess 720 may be formed on the second portion 710_2 of the first recess 710.

Referring to FIG. 5, a side portion 500_S of the first molding member 500 may have a stair-like shape in the recess 700.

The side portion 500_S of the first molding member 500 may include a first side 500_SW1, a second side 500_SW2, a first bottom surface 500_SB1, and a second bottom surface 500_SB2.

The first side 500_SW1 may be the side of the first molding member 500 in the first recess 710. The second side 500_SW2 may be the side of the first molding member 500 in the second recess 720.

The first bottom surface 500_SB1 may be the bottom surface of the first molding member 500 in the first recess 710. The second bottom surface 500_SB2 may be the bottom surface of the first molding member 500 in the second recess 720.

The first side 500_SW1 may protrude in a horizontal direction beyond the second side 500_SW2, relative to a side 300SW of the first semiconductor chip 300. For example, a first length R1 from the side 300SW of the first semiconductor chip 300 to the first side 500_SW1 in the horizontal direction may be greater than a second length R2 from the side 300SW of the first semiconductor chip 300 to the second side 500_SW2 in the horizontal direction.

The second bottom surface 500_SB2 of the side portion 500_S of the first molding member 500 may protrude in the third direction Z beyond the first bottom surface 500_SB1, relative to the bottom surface 500BS of the first molding member 500. For example, a second height H2 from the bottom surface 500BS of the first molding member 500 to the second bottom surface 500_SB2 may be greater than a first height H1 from the bottom surface 500BS of the first molding member 500 to the first bottom surface 500_SB1.

FIG. 6 is a cross-sectional view, taken along the horizontal direction, of a second recess 720, and FIG. 7 is a cross-sectional view illustrating the second recess 720 filled with a second molding member 600.

Referring to FIGS. 6 and 7, in a cross-sectional view taken along the horizontal direction, the second recess 720 may have a T shape.

The second recess 720 may include a third portion 720_1 with a third width W3 and a fourth portion 720_2 with a fourth width W4, which is greater than the third width W3. For example, the third portion 720_1 may extend in the second direction Y away from the first semiconductor chip 300, and the fourth portion 720_2 may extend in the first direction X that intersects the second direction Y, and the third portion 720_1 may be connected to the fourth portion 720_2. For example, the third portion 720_1 may be substantially perpendicular to the fourth portion 720_2. The fourth portion 720_2 may be positioned closer than the third portion 720_1 to the first semiconductor chip 300.

The first molding member 500 may include the T-shaped second recess 720. The first molding member 500 may at least partially surround the second recess 720. When the second molding member 600 fills the second recess 720, the second molding member 600 may be anchored by the first molding member 500. For example, the second molding member 600 becomes fixed to the first molding member 500.

Since the third portion 720_1 of the second recess 720 is positioned more outward than the fourth portion 720_2 of the second recess 720, which is wider than the third portion 720_1, the second molding member 600, filling the second recess 720, may be anchored by the first molding member 500.

FIG. 8 is a cross-sectional view, taken along the horizontal direction, of a first recess 710, and FIG. 9 is a cross-sectional view illustrating the first recess 710 filled with the second molding member 600.

Referring to FIGS. 8 and 9, in a cross-sectional view taken along the horizontal direction, the first recess 710 may have, for example, a T-shape. The first recess 710 may include a first portion 710_1 with a first width W1 and a second portion 710_2 with a second width W2, which is greater than the first width W1. For example, the first portion 710_1 may extend in the second direction Y away from the first semiconductor chip 300, and the second portion 710_2 may extend in the first direction X that intersects the second direction Y, and the first portion 710_1 may be connected to the second portion 710_2. For example, the first portion 710_1 may be substantially perpendicular to the second portion 710_2. The second portion 710_2 may be positioned closer than the first portion 710_1 to the first semiconductor chip 300.

The first molding member 500 may include the T-shaped first recess 710. The first molding member 500 may at least partially surround the first recess 710. When the second molding member 600 fills the first recess 710, the second molding member 600 may be anchored by the first molding member 500. For example, the second molding member 600 may be fixed to the first molding member 500.

Since the first portion 710_1 of the first recess 710 is positioned more outward than the second portion 710_2 of the first recess 710, which is wider than the first portion 710_1, the second molding member 600, filling the first recess 710, may be anchored by the first molding member 500.

In the case of a semiconductor package including an interposer according to a comparative example, when performing wafer level molding after mounting heterogeneous chips (e.g., memory chips, logic chips, etc.), delamination may occur at the interfaces of the semiconductor chips due to the difference in the coefficient of thermal expansion (CTE) and a reduced material bonding strength between the molding material for the semiconductor chips and the molding material for the interposer. In addition, as processes involving the application of heat are carried out, delamination worsens at the interfaces between heterogeneous or homogeneous materials.

However, the semiconductor package according to embodiments of the present inventive concept may include the interposer structure 200, first semiconductor chips 300, which are mounted on the interposer structure 200, the first molding member 500, which surrounds the first semiconductor chips 300 and includes recesses 700, and the second molding member 600, which surrounds the first molding member 500 and fills the recesses 700. The recesses 700 formed in the first molding member 500 may include first recesses 710, which are formed in the first areas S1, and second recesses 720, which are formed in the second areas S2. The first recesses 710 may include first portions 710_1 with the first width W1 and second portions 710_2 with the second width W2, which is greater than the first width W1. The second recesses 720 may include third portions 720_1 with the third width W3 and fourth portions 720_2 with the fourth width W4, which is greater than the third width W3. The third width W3 may be greater than the first width W1, and the fourth width W4 may be greater than the second width W2.

The first recesses 710 and the second recesses 720 may be filled with the second molding member 600. Due to the formation of the first recesses 710 and the second recesses 720 in the first molding member 500, the contact area between the first and second molding members 500 and 600 increases, potentially increasing the bonding strength between the first and second molding members 500 and 600.

Additionally, in a cross-sectional view taken along the horizontal direction, each of the first recesses 710 and the second recesses 720 may have, for example, an anchor shape or a T-shape. Thus, the second molding member 600, which fills the recesses 700, may be anchored by the first molding member 500. The shape of the recesses 700 may enable the first molding member 500 to strongly secure the second molding member 600. Due to the shape of the recesses 700, the bonding strength between the first and second molding members 500 and 600 can be increased. Accordingly, delamination between the first and second molding members 500 and 600 that may be caused by heat or pressure can be prevented.

The widths of the first recesses 710 and the second recesses 720 may vary. For example, the second recesses 720 may have a larger recess area than the first recesses 710. Thus, the semiconductor package according to embodiments of the present inventive concept can present a dual recess structure. In other words, the second molding member 600, filling the first recesses 710, can be anchored by the first molding member 500. Similarly, the second molding member 600, filling the second recesses 720, can be anchored by the first molding member 500.

In short, as the semiconductor package according to embodiments of the present inventive concept includes the first recesses 710 and the second recesses 720, the contact area between the first and second molding members 500 and 600 can be widened and increased. Additionally, the second molding member 600 can be anchored by the first molding member 500. Since the bonding strength between the first and second molding members 500 and 600 increases, distortion between materials that may be caused by heat or pressure can be prevented.

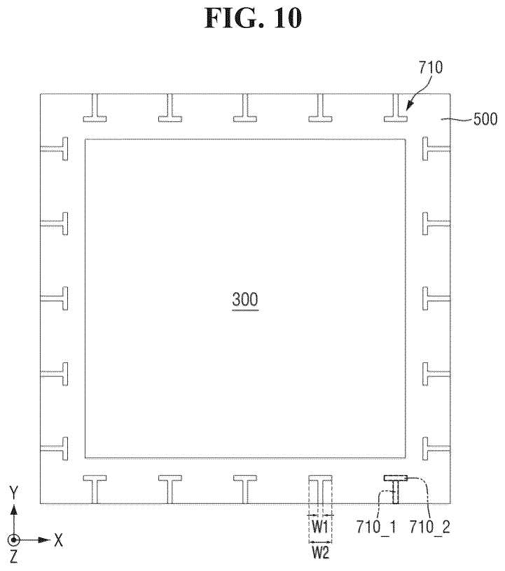

FIGS. 10 through 13 illustrate how to form recesses in a semiconductor package according to embodiments of the present inventive concept.

Referring to FIGS. 10 through 13, recesses 700 are formed before mounting a first semiconductor chip 300 on an interposer structure 200. The recesses 700 may include first recesses 71, which are formed in first areas S1, and second recesses 720, which are formed in the second areas S2. Here, the second areas S2 may be positioned on the first areas S1.

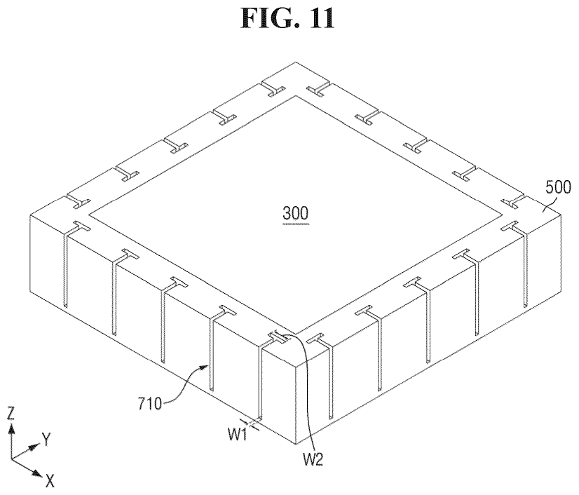

Referring to FIGS. 10 and 11, first, the first recesses 710 are formed in a first molding member 500 that at least partially surrounds the first semiconductor chip 300, by using laser cutting.

In embodiments of the present inventive concept, the first recesses 710 may be formed such that it extends towards, but does not expose, the bottom surface of the first molding member 500. For example, the bottom surfaces of the first recesses 710 may be spaced apart from the bottom surface of the first molding member 500. In addition, embodiments of the present inventive concept, the first recesses 710 may be formed to expose the bottom surface of the first molding member 500.

The first recesses 710 may have an angular T shape, but the present inventive concept is not limited thereto. The first recesses 710 may have another shape that can anchor the second molding member 600 to the first molding member 500, such as a U shape or an L shape. For example, the first recesses 710 may include first portions 710_1 and second portions 710_2. The first portions 710_1 may have a first width W1. The second portions 710_2 may have a second width W2, and the second width W2 may be greater than the first width W1. The first portions 710_1 may be further spaced apart than the second portions 710_2 from the first semiconductor chip 300. For example, the second portions 710_2 may be closer than the first portions 710_1 to the first semiconductor chip 300.

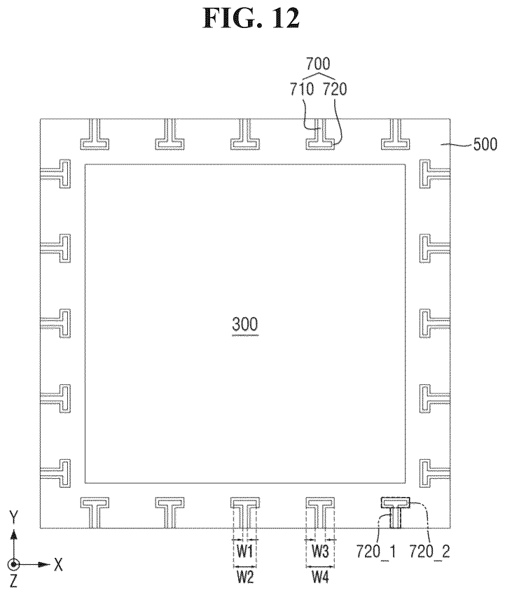

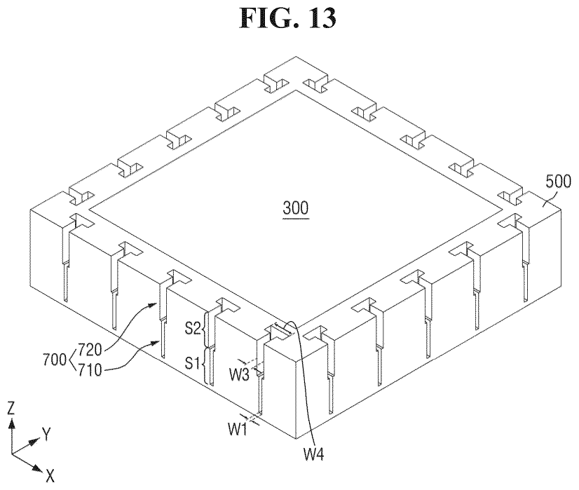

Thereafter, referring to FIGS. 12 and 13, subsequently, the second recesses 720 are formed where the first recesses 710 have been formed.

Using laser cutting, the second recesses 720, which have a larger area than the first recesses 710, may be formed at the locations of the first recesses 710. The second recesses 720 may be formed shallower than the first recesses 710. As a result, a dual recess structure can be formed.

The second recesses 720 may have an angular T shape, but the present inventive concept is not limited thereto. The second recesses 720 may have another shape that can anchor the second molding member 600 to the first molding member 500, such as a U shape or an L shape. For example, the second recesses 720 may include third portions 720_1 and fourth portions 720_2. The third portions 720_1 may have a third width W3. The fourth portions 720_2 may have a fourth width W4, and the fourth width W4 may be greater than the third width W3. The third width W3 of the second recesses 720 may be greater than the first width W1 of the first recesses 710. The fourth width W4 of the second recesses 720 may be greater than the second width W2 of the first recesses 710. The third portions 720_1 may be further spaced apart than the fourth portions 720_2 from the first semiconductor chip 300. In other words, the fourth portions 720_2 may be closer than the third portions 720_1 to the first semiconductor chip 300.

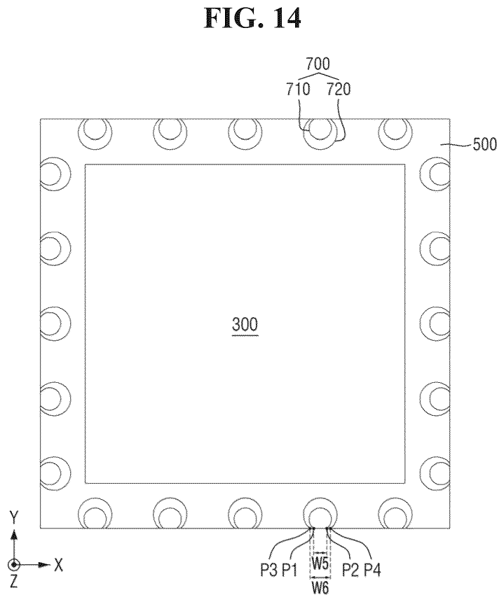

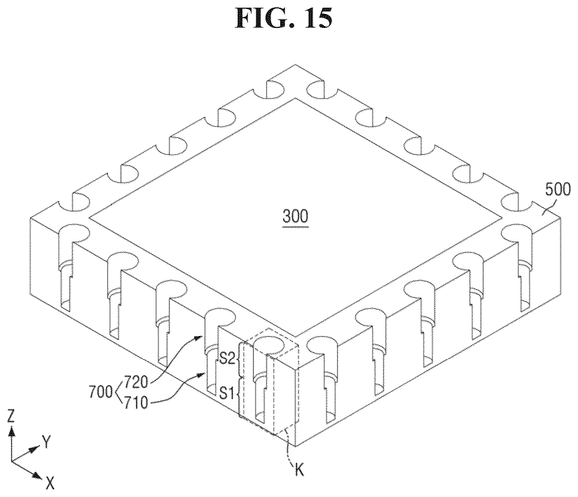

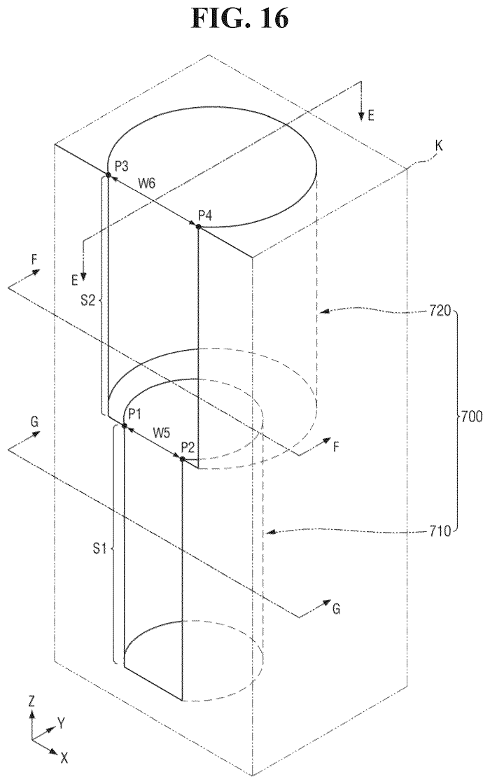

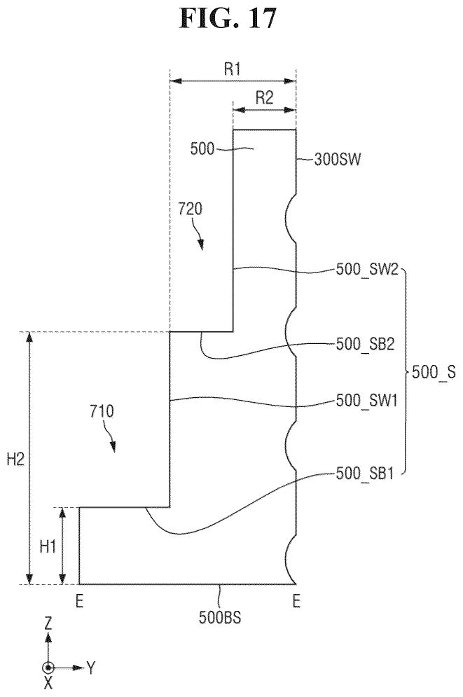

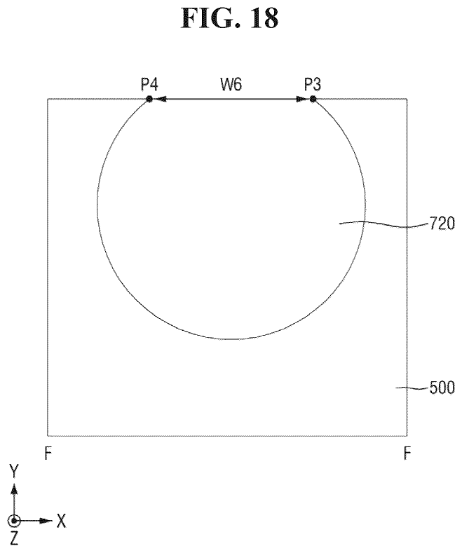

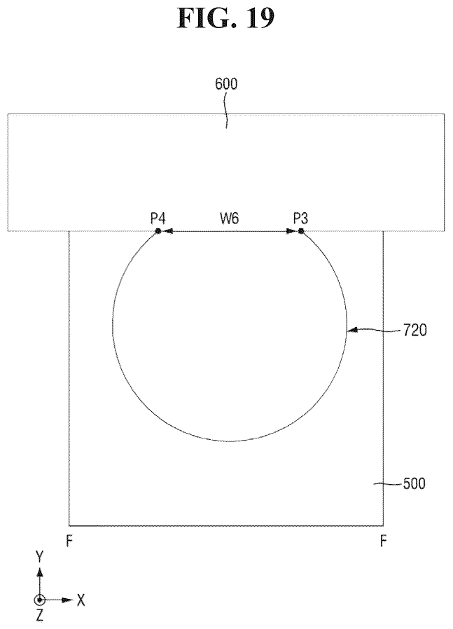

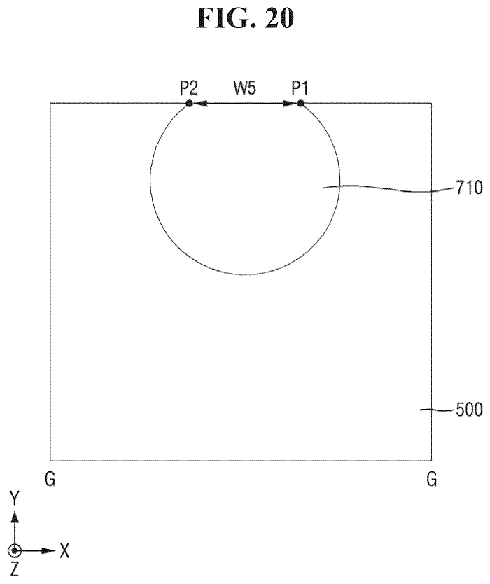

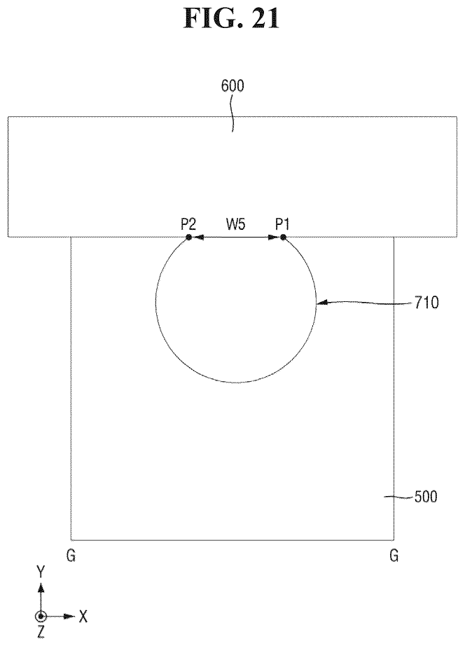

FIGS. 14 and 15 illustrate a semiconductor package according to embodiments of the present inventive concept. FIG. 16 is an enlarged drawing of part K of FIG. 15. FIG. 17 is a cross-sectional view taken along line E-E of FIG. 16. FIGS. 18 and 19 are cross-sectional views taken along line F-F of FIG. 16. FIGS. 20 and 21 are cross-sectional views taken along line G-G of FIG. 16. For convenience, content overlapping with what has been described above with reference to FIGS. 1 through 13 will be briefly explained or omitted.

Referring to FIGS. 14 and 15, a first semiconductor chip 300 may be at least partially surrounded by a first molding member 500. The first molding member 500 may include a plurality of recesses 700.

The recesses 700 may include first areas S1 and second areas S2. The recesses 700 may include first recesses 710, which are formed in the first areas S1, and second recesses 720, which are formed in the second areas S2.

From a planar perspective, the first recesses 710 and the second recesses 720 may have, for example, a shape including a chord and an arc. In embodiments of the present inventive concept, referring to FIG. 16, each of the first recesses 710 may have a shape formed by a chord and an arc between a first point P1 and a second point P2, and each of the second recesses 720 may have a shape formed by a chord and an arc between a third point P3 and a fourth point P4. For example, each of the first recesses 710 and second recesses 720 may have a circular or rounded shape.

A length W5 of a straight line connecting the first and second points P1 and P2 may be shorter than a length W6 of a straight line connecting the third and fourth points P3 and P4. For example, the second recesses 720 may have a larger area than the first recesses 710.

Referring to FIGS. 16 and 17, a recess 700, which includes first and second recesses 710 and 720, may be formed in the first molding member 500 in the third direction Z. The second recess 720 may be formed on the first recess 710.

In the recess 700, a side portion 500_S of the first molding member 500 may have a stair-like shape. The side portion 500_S of the first molding member 500 may include a first side 500_SW1, a second side 500_SW2, a first bottom surface 500_SB1, and a second bottom surface 500_SB2. Relative to a side 300SW of the first semiconductor chip 300, the first side 500_SW1 may protrude in the horizontal direction beyond the second side 500_SW2. For example, a first length R1 from the side 300SW of the first semiconductor chip 300 to the first side 500_SW1 in the horizontal direction may be greater than a second length R2 from the side 300SW of the first semiconductor chip 300 to the second side 500_SW2 in the horizontal direction.

Relative to the bottom surface 500BS of the first molding member 500, the second bottom surface 500_SB2 of the side portion 500_S of the first molding member 500 may protrude in the third direction Z beyond the first bottom surface 500_SB1. For example, a second height H2 from the bottom surface 500BS to the second bottom surface 500_SB2 of the first molding member 500 may be greater than a first height H1 from a bottom surface 500BS of the first molding member 500 to the first bottom surface 500_SB1.

FIG. 18 is a cross-sectional view, taken along a horizontal direction, of a second recess 720, and FIG. 19 is a drawing illustrating the second recess 720 filled with the second molding member 600.

The first molding member 500 may at least partially surround the second recess 720. Since from a planar perspective, the second recess 720 has, for example, a shape formed by a chord and an arc between the third and fourth points P3 and P4, the second molding member 600, filling the second recess 720, may be anchored by the first molding member 500.

FIG. 20 is a cross-sectional view, taken along the horizontal direction, of a first recesses 710, and FIG. 21 is a drawing illustrating the first recess 710 filled with the second molding member 600.

The first molding member 500 may at least partially surround the first recess 710. Since from a planar perspective, the first recesses 710 have, for example, a shape formed by a chord and an arc between the first and second points P1 and P2, the second molding member 600, filling the first recess 710, may be anchored by the first molding member 500.

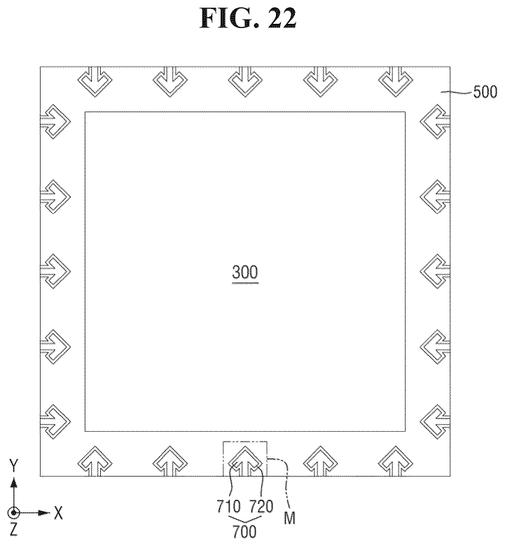

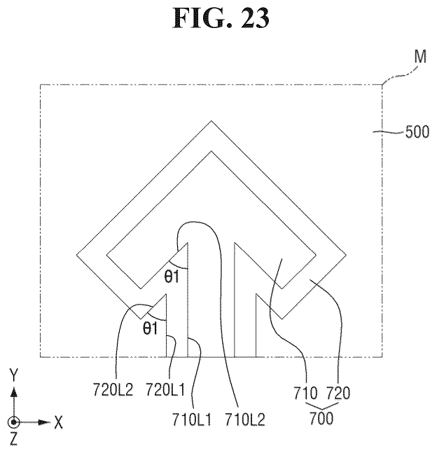

FIGS. 22 through 24 illustrate recesses in a semiconductor package according to embodiments of the present inventive concept. FIG. 23 is an enlarged diagram of part M of FIG. 22. For convenience, content overlapping with what has been described above with reference to FIGS. 1 through 21 will be briefly explained or omitted.

Referring to FIGS. 22 through 24, first recesses 710 and second recesses 720 may have an arrow shape.

The first recesses 710 may include first surfaces 710L1 and second surfaces 710L2. The second recesses 720 may include third surfaces 720L1 and fourth surfaces 720L2.

The first surfaces 710L1 of the first recesses 710 may be perpendicular or parallel to the sides of a first molding member 500. A first angle θ1 formed by the first surfaces 710L1 and the second surfaces 710L2 of the first recesses 710 may be an acute angle.

The third surfaces 720L1 of the second recesses 720 may be perpendicular or parallel to the sides of the first molding member 500. A first angle θ1 formed by the third surfaces 720L1 and the fourth surfaces 720L2 of the second recesses 720 may be an acute angle.

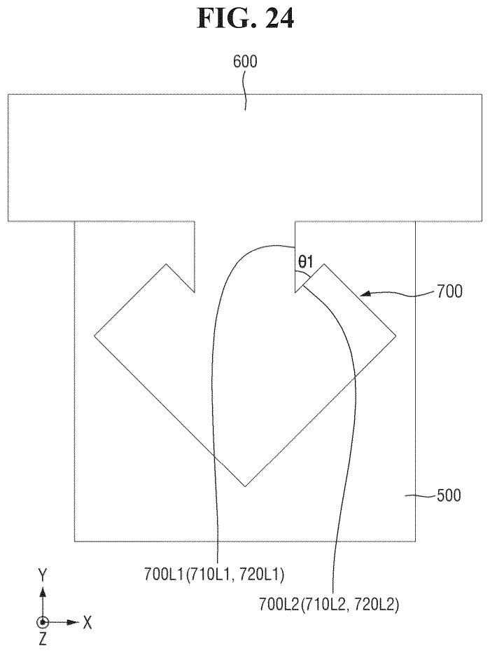

Referring to FIG. 24, a second molding member 600 may fill the first recesses 710 and the second recesses 720. The second molding member 600, filling the first recesses 710 and the second recesses 710 and 720, may be anchored by the first molding member 500.

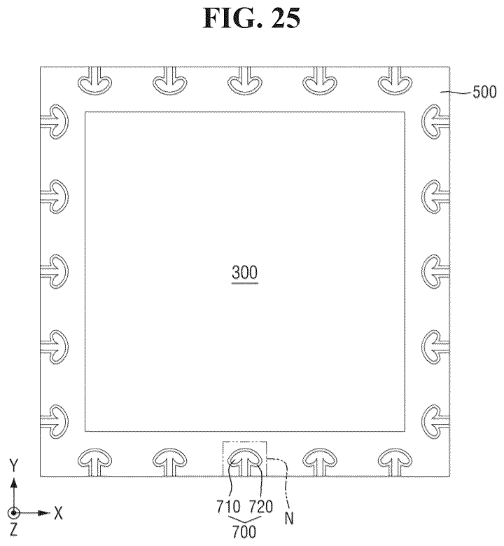

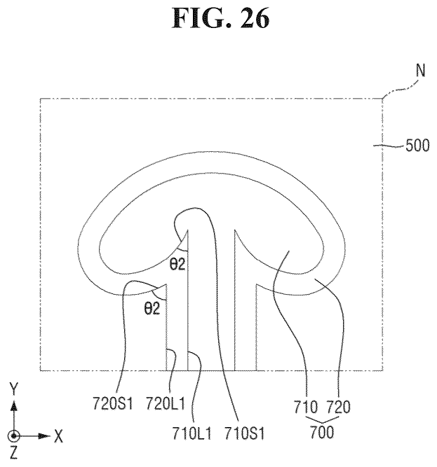

FIGS. 25 through 27 are diagrams illustrating recesses in a semiconductor package according to embodiments of the present inventive concept. FIG. 26 is an enlarged diagram of part N of FIG. 25. For convenience, content overlapping with what has been described above with reference to FIGS. 1 through 21 will be briefly explained or omitted.

Referring to FIGS. 25 through 27, first recesses 710 and second recesses 720 may have a bean shape. For example, each of the first recesses 710 and second recesses 720 may have a bent elliptical shape.

The first recesses 710 may include first surfaces 710L1 and first curved surfaces 710S1. The second recesses 720 may include third surfaces 720L1 and second curved surfaces 720S1.

The first surfaces 710L1 of the first recesses 710 may be perpendicular or parallel to the sides of a first molding member 500. A second angle θ2 formed by the first surfaces 710L1 and the first curved surfaces 710S1 of the first recesses 710 may be an acute angle.

The third surfaces 720L1 of the second recesses 720 may be perpendicular or parallel to the sides of the first molding member 500. A second angle θ2 formed by the third surfaces 720L1 and the second curved surfaces 720S1 of the second recesses 720 may be an acute angle.

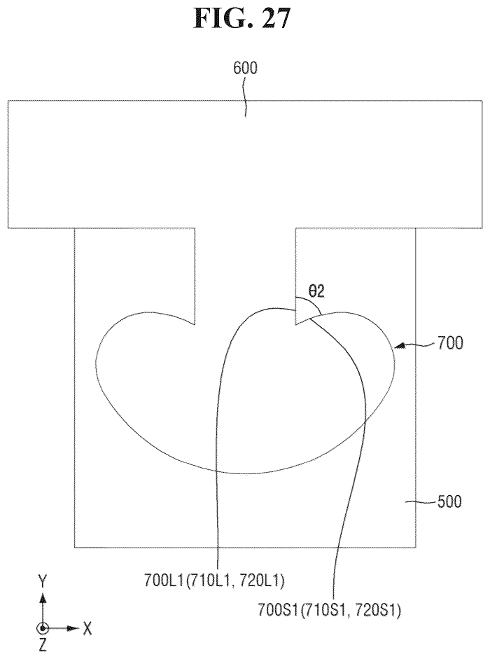

Referring to FIG. 27, a second molding member 600 may fill the first recesses 710 and the second recesses 720. The second molding member 600, filling the first recesses 710 and the second recesses 720, may be anchored by the first molding member 500.

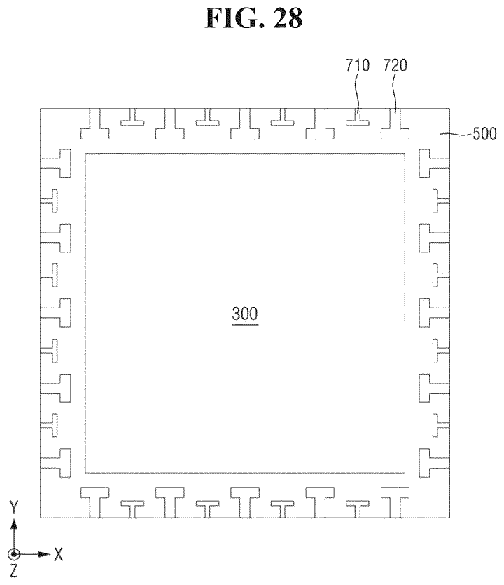

FIGS. 28 through 30 are diagrams illustrating recesses in semiconductor packages according to embodiments of the present inventive concept. For convenience, content overlapping with what has been described above with reference to FIGS. 1 through 27 will be briefly explained or omitted.

Referring to FIGS. 28 through 30, recesses formed in a first molding member 500 may have various shapes.

Referring to FIG. 28, in embodiments of the present inventive concept, first recesses 710 and second recesses 720 may be alternately arranged. The first recesses 710 may be formed between the second recesses 720. The second recesses 720 may be formed between the first recesses 710.

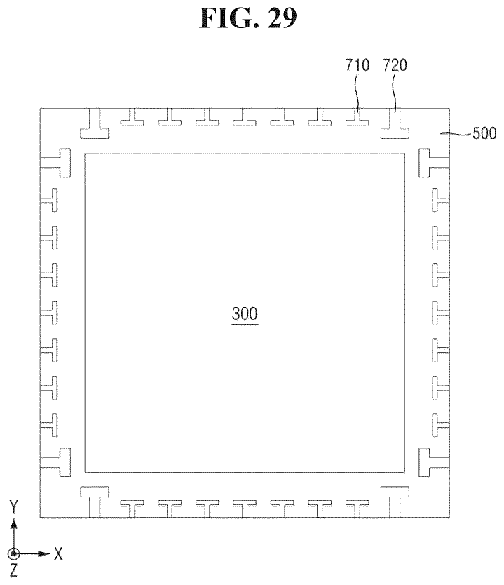

Referring to FIG. 29, in embodiments of the present inventive concept, second recesses 720 may be formed at both ends of each of the sides of the first molding member 500, with first recesses 710 formed therebetween. Since the second recesses 720 have a larger area than that of the first recesses 710, the second recesses 720 may be formed at both ends of each of the sides of the first molding member 500, where the bonding strength between the first molding member 500 and a second molding member 600 may be relatively weak, and the first recesses 710 may be formed between the second recesses 720.

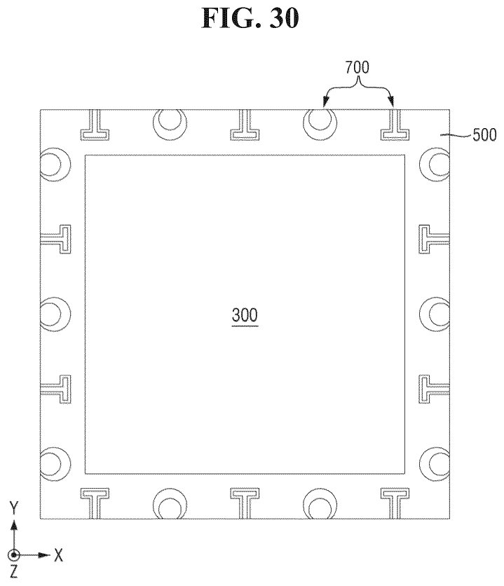

Referring to FIG. 30, in embodiments of the present inventive concept, recesses 700 of different shapes may be formed in a first molding member 500. For example, T-shaped recesses 700 and recesses 700 that have a shape formed by a chord and an arc may be alternately arranged.

While the present inventive concept has been described with reference to embodiments thereof, it will be understood by those of ordinary skill in the art that various changes in form and details may be made thereto without departing from the spirit and scope of the present inventive concept.

What is claimed is:

1. A semiconductor package comprising:
a substrate;
first semiconductor chips mounted on the substrate;
a second semiconductor chip mounted on the substrate and spaced apart from the first semiconductor chips;
a first molding member covering sides of each of the first semiconductor chips; and
a second molding member covering the first semiconductor chips and the second semiconductor chip, and disposed on the substrate,
wherein
each of the first semiconductor chip includes a plurality of semiconductor chips that are stacked on each other along a first direction,
the first molding member includes recesses, which are formed to extend along the first direction,
the recesses include first portions, which extend to edges of the first molding member and have a first width, and second portions, which are connected to the first portions and are positioned more inward into the first molding member than the first portions,
the second portions have a second width that is greater than the first width, and
the second molding member fills at least parts of the recesses.

2. The semiconductor package of claim 1, wherein
the first width of the first portions is substantially constant along the first direction, and
the second width of the second portions is substantially constant along the first direction.

3. The semiconductor package of claim 2, wherein
bottom surfaces of the recesses are spaced apart from a bottom surface of the second molding member.

4. The semiconductor package of claim 1, wherein the recesses have first areas and second areas, which are formed on the first areas, and include first recesses and second recesses, wherein the first recesses are formed in the first areas and include the first portions, which have the first width, and the second portions, which have the second width, wherein the second recesses are formed in the second areas and include third portions and fourth portions, wherein the third portions have a third width and extend to edges of the first molding member, and wherein the fourth portions are connected to the third portions and have a fourth width that is greater than the third width.

5. The semiconductor package of claim 4, wherein
the third width is greater than the first width, and
the fourth width is greater than the second width.

6. The semiconductor package of claim 5, wherein in the recesses where the first and second molding members contact each other, side portions of the first molding member have a stair-like shape.

7. The semiconductor package of claim 5, wherein relative to the sides of each of the first semiconductor chips, first sides of the first molding member in the first areas protrude in a second direction beyond second sides of the first molding member in the second areas, wherein the second direction intersects the first direction.

8. The semiconductor package of claim 1, wherein the second molding member, filling the first portions and the second portions of the recesses, has a T shape.

9. The semiconductor package of claim 7, wherein the first molding member anchors the second molding member that fills the first portions and the second portions of the recesses.

10. The semiconductor package of claim 1, wherein
the first semiconductor chips are memory chips, and
the second semiconductor chip is a logic chip.

11. A semiconductor package comprising:
an interposer structure;
first semiconductor chips mounted on the interposer structure and including a stack of a plurality of semiconductor chips;
a plurality of first bumps electrically connecting the interposer structure to the first semiconductor chips and disposed between the interposer structure and the first semiconductor chips;
a first molding member at least partially surrounding the first semiconductor chips and including a plurality of recesses, which are formed in a stacking direction of the plurality of semiconductor chips; and
a second molding member covering the first semiconductor chips and disposed on the interposer structure,
wherein
the recesses have first areas and second areas, which are formed on the first areas, and include first recesses and second recesses, wherein the first recesses are formed in the first areas and include first portions, which have a first width, and second portions, which have a second width that is greater than the first width, wherein the second recesses are formed in the second areas and include third portions, which have a third width, and fourth portions, which have a fourth width that is greater than the third width, and
the second molding member fills the first recesses and the second recesses.

12. The semiconductor package of claim 11, wherein
the third width is greater than the first width, and
the fourth width is greater than the second width.

13. The semiconductor package of claim 11, wherein the second molding member, which fills the first recesses and the second recesses, has a T shape.

14. The semiconductor package of claim 13, wherein the first molding member anchors the second molding member that fills the first portions, the second portions, the third portions, and the fourth portions.

15. The semiconductor package of claim 12, wherein in the recesses where the first and second molding members contact each other, side portions of the first molding member have a stair-like shape.

16. The semiconductor package of claim 11, wherein a first length from sides of each of the first semiconductor chips to first sides of the first molding member in the first areas is greater than a second length from the sides of each of the first semiconductor chips to second sides of the first molding member in the second areas.

17. The semiconductor package of claim 11, further comprising:
a second semiconductor chip spaced apart from the first semiconductor chips and mounted on the interposer structure;
a plurality of second bumps electrically connecting the interposer structure to the second semiconductor chip; and
an underfill filling gaps between the interposer structure and the first semiconductor chips and between the interposer structure and the second semiconductor chip and covering the plurality of first bumps and the plurality of second bumps.

18. The semiconductor package of claim 17, further comprising:
a circuit board on which the interposer structure is disposed;
first solder balls electrically connecting the interposer structure to the circuit board; and
a stiffener spaced apart from the interposer structure and disposed on the circuit board,
wherein the interposer structure includes an interposer, an interlayer insulating layer, which is disposed on the interposer, through vias, which penetrate the interposer, and redistribution layers, which are formed in the interlayer insulating layer.

19. The semiconductor package of claim 18, wherein
the first semiconductor chips are memory chips, and
the second semiconductor chip is a logic chip.

20. A semiconductor package comprising:
a circuit board;
an interposer structure disposed on the circuit board;
first solder balls electrically connecting the interposer structure to the circuit board;
memory chips mounted on the interposer structure and including a stack of a plurality of semiconductor chips;
a logic chip spaced apart from the memory chips and mounted on the interposer structure;
a plurality of first bumps electrically connecting the interposer structure to the memory chips, and electrically connecting the interposer structure to the logic chip, wherein the plurality of first bumps are disposed between the interposer structure and the memory chips and between the interposer structure and the logic chip;
a first molding member at least partially surrounding the memory chips and including a plurality of recesses, which extend in a first direction; and
a second molding member covering the memory chips and the logic chip, and covering the first molding member,
wherein
the recesses include first recesses, which are formed in first areas, and second recesses, which are formed in second areas that are formed on the first areas,
the first recesses include first portions, which have a first width, and second portions, which have a second width that is greater than the first width,
the second recesses include third portions, which have a third width, and fourth portions, which have a fourth width that is greater than the third width,
the third width is greater than the first width,
the fourth width is greater than the second width,
the second molding member fills the first recesses and the second recesses and has a T shape, and
in the recesses, sides of the first molding member have a stair-like shape.
